(19) United States
(12) Patent Application Publication
(10) Pub. No.: US 2010/0210065 A1
(43) Pub. Date: Aug. 19, 2010

(54) METHOD OF MANUFACTURING SOLAR CELL

(75) Inventors: Yasuhiro AIDA, Tokyo (JP); Masato SUSUKIDA, Tokyo (JP)

Correspondence Address: OLIFF & BERRIDGE, PLC, P.O. BOX 320850, ALEXANDRIA, VA, 22320-4850, US

(73) Assignee: TDK CORPORATION, Tokyo (JP)

(21) Appl. No.: 12/702,871

(22) Filed: Feb. 9, 2010

(30) Foreign Application Priority Data
Feb. 18, 2009 (JP) P2009-035602

(51) Int. Cl. H01L 21/363

(52) U.S. Cl. 438/95; 257/E21.462

(57) ABSTRACT

A method of manufacturing a solar cell is provided, which can enhance the carrier concentration, so as to increase the open-circuit voltage, short-circuit current, and fill factor (F.F.), thereby raising the conversion efficiency. The method of manufacturing a solar cell in accordance with the present invention comprises a sputtering step of forming a layer containing Ib and IIIb group elements and Se on a substrate by sputtering with a target containing a Ib group element and a target containing a IIIb group element in an atmosphere containing Se; and a heat treatment step of heating the layer.

### BACKGROUND OF THE INVENTION

1. Field of the Invention

The present invention relates to a method of manufacturing a solar cell.

2. Related Background Art

In place of bulk crystalline silicon solar cells which have been coming into wider use, thin-film solar cells using thin-film semiconductor layers as photo-absorber have been under development. Among them, thin-film solar cells employing compound semiconductor layers containing Ib, IIIb, and VIb group elements as their photo-absorbing layers are expected to be next-generation solar cells, since they exhibit high energy conversion efficiencies and are less likely to be deteriorated by light. Specifically, thin-film solar cells using CuInSe₂ (hereinafter referred to as “CIS”) constituted by Cu, In, and Se or Cu(In, Ga)Se₂ (hereinafter referred to as “CIGS”) partly replacing In which is a IIIb group element in CIS with Ga as their photo-absorbing layers have yielded high conversion efficiencies (see Prog. Photovolt: Res. Appl. (2008), 16:235-239).

A method known as a selenization has typically been employed as a method for forming a photo-absorbing layer constituted by CIGS. The selenization forms a photo-absorbing layer precursor by laminating respective thin films of Cu, In, Ga, and Se, which are raw materials for the photo-absorbing layers, or their alloy films by sputtering and then heat-treats the precursor, so as to form a photo-absorbing layer constituted by a CIGS film.

As an example of the selenization, Japanese Patent Publication No. 3897622 discloses a method forming a precursor by laminating alloy films upon sputtering with their corresponding targets of Cu—Ga and In—Ga—Se alloys and then heat-treating the precursor in a selenium atmosphere, so as to form a CIGS film.

As another example of the selenization, Japanese Patent Publication No. 3831592 discloses a method forming a precursor by sputtering with elements other than selenium and then heat-treating the precursor while supplying the precursor with selenium by a process (e.g., vapor deposition) other than sputtering.

### SUMMARY OF THE INVENTION

In the method described in Japanese Patent Publication No. 3897622, one target contains Se, while the other does not. Therefore, the Se concentration varies within the films of the precursor. Also, the target containing Se is likely to change over time. This is because Se is easy to escape from the target under the influence of heat and plasmas, so that the ratio of Se in the target decreases from its initial value as time passes. These make the Se concentration in the films of the precursor uneven and the amount of Se contained in the whole precursor insufficient. For overcoming the unevenness in the Se concentration and the shortage in the Se amount, the precursor must be heat-treated in a selenium atmosphere. Heat-treating the precursor in a selenium atmosphere can compensate for the lack of selenium, thereby promoting the forming of a uniform CIGS film. The heat treatment in a selenium atmosphere, however, drastically expands the volume of the precursor, thereby causing defects such as transitions and microcracks in the films of the precursor. As the density of defects in the precursor becomes greater, defect levels are more likely to occur, thereby causing the carrier mobility to decrease and allowing photogenerated carriers to recombine. This will deteriorate solar cell characteristics.

It is necessary for the method described in Japanese Patent Publication No. 3831592 to supply the precursor with a large amount of selenium in the heat treatment, which causes the precursor to expand its volume drastically in the heat treatment, thereby failing to inhibit defects from occurring.

As mentioned above, both of the conventional methods described in Japanese Patent Publication Nos. 3897622 and 3831592 add selenium to the precursor during the heat treatment after the sputtering and fail to prevent the precursor from drastically expanding its volume with selenium added thereto during the heat treatment. Therefore, the CIGS films produced by these methods may contain a large number of defects. Solar cells using such CIGS films may fail to yield favorable characteristics. Specifically, in solar cells using CIGS films formed by the conventional methods, the drop in the carrier concentration due to defect levels generated in the CIGS films causes the open-circuit voltage, short-circuit current, and fill factor (F.F.) to decrease, thereby lowering the conversion efficiency. Also, in the CMS films formed by the methods described in Japanese Patent Publication Nos. 3897622 and 3831592, the Se distribution may become uneven in the depth and in-plane directions of the films, thereby increasing fluctuations in characteristics when making solar cells with greater areas.

In view of the problems of the prior art mentioned above, it is an object of the present invention to provide a method of manufacturing a solar cell which can increase the open-circuit voltage, short-circuit current, and fill factor (F.F.), thereby enhancing the conversion efficiency.

For achieving the above-mentioned object, the method of manufacturing a solar cell in accordance with the present invention comprises a sputtering step of forming a layer containing Ib and IIIb group elements and Se on a substrate by sputtering with a target containing a Ib group element and a target containing a IIIb group element in an atmosphere containing Se; and a heat treatment step of heating the layer. In the present invention, the “substrate” refers to a rear electrode layer and the like formed on a soda-lime glass sheet, for example, while the “layer” refers to a p-type photo-absorbing layer (p-type semiconductor layer) and the like formed on the rear electrode layer, for example.

The present invention enhances the carrier concentration in the resulting solar cell, thereby increasing the open-circuit voltage, short-circuit current, and fill factor (F.F.). Therefore, the present invention can make it possible for the resulting solar cell to attain a conversion efficiency higher than that in solar cells comprising p-type photo-absorbing layers obtained by the conventional methods.

Preferably, in the present invention, the sputtering step introduces H₂Se into the atmosphere. In the present invention, the sputtering step may vaporize solid Se and introduce thus vaporized Se (Se vapor) into the atmosphere. The advantageous effects of the present invention are easier to obtain when H₂Se or solid Se is employed as a source for supplying Se contained in the atmosphere.

Preferably, in the present invention, the heat treatment step heats the layer in an atmosphere containing Se. This makes it easier to overcome the shortage of Se in the layer and disperses Ib and IIIb group elements uniformly in the layer, whereby a semiconductor layer having a uniform composition in which Se is sufficient can be obtained more easily. As a result, the advantageous effects of the present invention are easier to attain.

In the present invention, the heat treatment step may introduce H₂Se into the atmosphere, or vaporize solid Se and introduce thus vaporized Se into the atmosphere. This makes it easier to obtain the advantageous effects of the present invention.

Preferably, in the present invention, the Ib group element comprises Cu, while the IIIb group element comprises at least one of In and Ga. This makes it possible to form a semiconductor layer constituted by CIS, CGS, CIGS, or the like.

The present invention can provide a method of manufacturing a solar cell which can enhance the carrier concentration, so as to increase the open-circuit voltage, short-circuit current, and fill factor (F.F.), thereby raising the conversion efficiency.

### BRIEF DESCRIPTION OF THE DRAWINGS

FIG. 1 is a schematic sectional view of a solar cell obtained by the method of manufacturing a solar cell in accordance with an embodiment of the present invention.

### DESCRIPTION OF THE PREFERRED EMBODIMENTS

In the following, a preferred embodiment of the present invention will be explained in detail with reference to the drawing. In the drawing, the same or equivalent constituents will be referred to with the same signs. Vertical and horizontal positional relationships are as illustrated in the drawing. Overlapping explanations will be omitted.

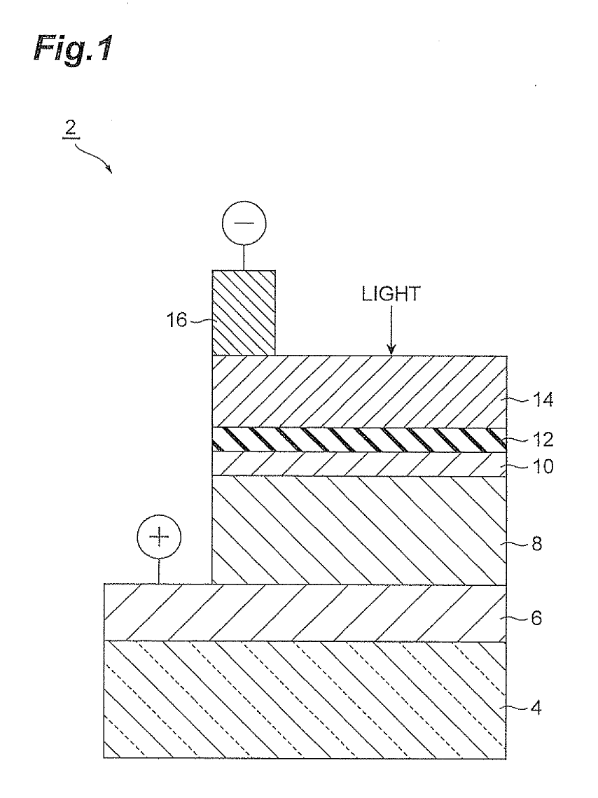

As illustrated in FIG. 1, a solar cell 2 obtained by the method of manufacturing a solar cell in accordance with this embodiment is a thin-film solar cell comprising a soda-lime glass sheet 4, a rear electrode layer 6 formed on the soda-lime glass sheet 4, a p-type photo-absorbing layer 8 (p-type semiconductor layer) formed on the rear electrode layer 6, an n-type buffer layer 10 (n-type semiconductor layer) formed on the p-type photo-absorbing layer 8, a semi-insulating layer 12 formed on the n-type buffer layer 10, a window layer 14 (transparent conductive layer) formed on the semi-insulating layer 12, and an upper electrode 16 (lead electrode) formed on the window layer 14.

First, in this embodiment, the rear electrode layer 6 is formed on the soda-lime glass sheet 4. The rear electrode layer 6 is typically a metal layer constituted by Mo. An example of the method for forming the rear electrode layer 6 is sputtering with an Mo target.

After forming the rear electrode layer 6 on the soda-lime glass sheet 4, a sputtering step forms a layer (a precursor layer for the p-type photo-absorbing layer 8) containing Ib and Mb group elements and Se on the rear electrode layer 6 by sputtering with a target containing a Ib group element and a target containing a IIb group element in an atmosphere containing Se.

The sputtering step may introduce H₂Se into the atmosphere, or vaporize solid Se and introduce thus vaporized Se into the atmosphere. That is, H₂Se or solid Se may be employed as a source for supplying Se in the atmosphere. In other words, Se contained in the atmosphere in the sputtering step of this embodiment is not derived from any of the targets and layers, but from an H₂Se gas or solid Se separate therefrom. As a sputtering gas, a noble gas such as Ar may be employed, for example. The respective times for sputtering with the targets and the concentration and partial pressure of Se in the atmosphere may be adjusted appropriately according to the composition of the p-type photo-absorbing layer 8 to be obtained.

Among Ib group elements such as Cu, Ag, and Au, Cu is used preferably in this embodiment. Among IIIb group elements such as B, Al, Ga, In, and Ti, at least one of In and Ga is used preferably, most preferably both of In and Ga.

When the Ib group element is Cu while the IIIb group elements are In and Ga, the p-type photo-absorbing layer 8 constituted by CIGS (hereinafter referred to as “p-CIGS layer 8”) can be formed.

Adjusting the molar ratio between In and Ga in the p-CIGS layer 8 can regulate its band gap Eg within the range of 1.0 to 1.6 eV and make its photo-absorption coefficient greater than 10⁵ cm⁻¹. A solar cell comprising such a p-CIGS layer 8 can achieve a high conversion efficiency.

In the following, a case where the p-CIGS layer 8 is formed on the rear electrode layer 6 will be explained.

When forming the p-CIGS layer 8 on the rear electrode layer 6, a target constituted by a CuGa alloy and a target constituted by elemental In may be used, for example. In place of the target constituted by elemental In, a target constituted by In₂Se₃ containing Se may be used.

In the sputtering step, the temperature of the rear electrode layer 6 (substrate) formed on the soda-lime glass sheet 4 is preferably set to 200 to 500° C., more preferably 400 to 500° C. When the substrate temperature is too low, the p-CIGS layer 8 is easier to peel off from the rear electrode layer 6, while the selenium content in the p-CIGS layer 8 tends to decrease. When the substrate temperature is too high, on the other hand, the soda-lime glass sheet 4, rear electrode layer 6, or p-CIGS layer 8 is easier to soften and deform. These tendencies can be suppressed when the substrate temperature is held within the range mentioned above.

After the sputtering step, the precursor layer is heated in a heat treatment step. This yields the p-CIGS layer 8.

Preferably, the heat treatment step heats the precursor layer in an atmosphere containing Se. This makes it easier to overcome the shortage of Se in the precursor layer and disperses Cu, In, and Se uniformly in the precursor layer. Therefore, the p-CIGS layer 8 having a uniform composition in which Se is sufficient can be obtained more easily.

The heat treatment step may introduce H₂Se into the atmosphere, or vaporize solid Se and introduce thus vaporized Se into the atmosphere. The advantageous effects of the present invention can also be obtained when the precursor layer is heated in an atmosphere constituted by a noble gas such as Ar with no Se instead of the Se-containing atmosphere in the heat treatment step.

In the heat treatment step, the temperature of the atmosphere is preferably 400 to 520° C., more preferably 500 to 520° C. When the temperature of the atmosphere is too low, the crystal growth and atomic interdiffusion in the precursor may not be promoted, whereby the p-CIGS layer 8 tends to increase defects and make its composition uneven. When the temperature of the atmosphere is too high, on the other hand, the soda-lime glass sheet 4, rear electrode layer 6, or p-CIGS layer 8 tends to warp or melt. These tendencies can be suppressed when the substrate temperature is held within the range mentioned above.

After forming the p-CIGS layer 8, the n-type buffer layer 10 is formed thereon. Examples of the n-type buffer layer 10 include layers of CdS, Zn(S, O, OH), ZnMgO, and Zn(Oₓ, S₁₋ₓ) where x is a positive real number less than 1. The CdS and Zn(S, O, OH) layers can be formed by chemical bath deposition. The ZnMgO layer can be formed by chemical vapor deposition such as MOCVD (Metal Organic Chemical Vapor Deposition) or sputtering. The Zn(Oₓ, S₁₋ₓ) layer can be formed by ALD (Atomic Layer Deposition).

After forming the n-type buffer layer 10, the semi-insulating layer 12 is formed thereon, the window layer 14 is formed on the semi-insulating layer 12, and the upper electrode 16 is formed on the window layer 14. This yields the thin-film solar cell 2. An antireflection layer constituted by MgF₂ may be formed on the window layer 14.

An example of the semi-insulating layer 12 is a ZnO layer. Examples of the window layer 14 include those made of ZnO:B and ZnO:Al. The upper electrode 16 is constituted by a metal such as Al or Ni, for example. The semi-insulating layer 12, window layer 14, and upper electrode 16 can be formed by sputtering or MOCVD, for example.

By sputtering with targets in an atmosphere containing Se in the sputtering step, this embodiment can control the composition of the precursor layer more easily than the conventional methods described in Japanese Patent Publication Nos. 3897622 and 3831592, and thus can restrain the precursor layer from drastically expanding its volume in the heat treatment step after the sputtering step. As a result, this embodiment can inhibit defects from occurring in the p-CIGS layer 8 more effectively than the conventional methods. In a solar cell comprising the p-CIGS layer 8 with less defects, the drop in the carrier concentration due to defect levels is harder to occur than in the solar cells comprising the conventional p-CIGS layers, so that the open-circuit voltage, short-circuit current, and fill factor (F.F.) increase, thereby improving the conversion efficiency. Also, this embodiment can make the Se concentration distribution in the depth and in-plane directions of the p-CIGS layer 8 more uniform than in the conventional p-CIGS layer. Therefore, the solar cell obtained by this embodiment yields less fluctuations in characteristics than the conventional solar cells when made with a greater area. Hence, the solar cell obtained by this embodiment can easily increase its area.

In the method described in Japanese Patent Publication No. 3897622, the desorption of Se from the target and the difference in Se contents between the targets in the sputtering step may cause the shortage in Se and its uneven concentration distribution in the resulting layer, and the addition of Se in the heat treatment step may expand the layer. By contrast, this embodiment supplies a sufficient amount of Se or H₂Se into the atmosphere in the sputtering step and thus can prevent these problems.

In the method described in Japanese Patent Publication No. 3831592, the thin film obtained by the sputtering step contains no Se because of sputtering with the targets containing no Se. For adding Se into the thin film, the precursor must be supplied with a large amount of Se in the heat treatment step subsequent to the sputtering step. As a result, the method described in Japanese Patent Publication No. 3831592 may incur a drastic volumetric expansion due to the large amount of Se supplied. In this embodiment, by contrast, Se is less likely to be in short in the layer, since the sputtering step supplies the layer with Se in the atmosphere. Therefore, it is not always necessary for this embodiment to add a large amount of Se to the layer in the heat treatment step, whereby the layer can be prevented from drastically expanding its volume with Se supplied thereto.

In contrast to the conventional methods, this embodiment can obtain a solar cell having desirable characteristics without introducing Se in the atmosphere during the heat treatment of the precursor layer. That is, this embodiment can save the operation of introducing Se into the atmosphere during the heat treatment, thereby simplifying the manufacturing method and lowering its cost.

Though a preferred embodiment of the method of manufacturing a solar cell in accordance with the present invention is explained in detail in the foregoing, the present invention is not limited to the above-mentioned embodiment.

Appropriately selecting targets used for the sputtering step can manufacture solar cells comprising p-type semiconductor layers constituted by CuInSe₂, CuGaSe₂, Cu(In, Ga)(S, Se)₂, CuIn₃Se₅, CuGa₃Se₅, Cu(In, Ga)₃Se₅, Cu(In, Ga)₃(S, Se)₅, CuAlSe₂, Cu(In, Al)Se₂, Cu(Ga, Al)Se₂, AgInSe₂, and Ag(In, Ga)Se₂, for example.

The targets used for the sputtering step is not always required to contain Se. The present invention supplies Se in the atmosphere to the layer in the sputtering step, and thus can disperse Se uniformly in the layer and make the latter contain a desirable amount of Se.

The present invention will now be explained more specifically with reference to examples and comparative examples, but should not be restricted to the following examples.

### Example 1

After washing and drying a soda-lime glass sheet having a size of 10 cm (length)×10 cm (width)×1 mm (thickness), a film-like rear electrode constituted by elemental Mo was formed thereon by sputtering. The thickness of the rear electrode was 1 μm.

The rear electrode (substrate) formed on the soda-lime glass sheet was placed in a chamber of a sputtering apparatus, and the chamber was vacuumed. While continuously supplying an Ar gas (sputtering gas) and an H₂Se gas into the chamber, sputtering was performed with a target constituted by a Cu—Ga alloy containing 20 at % of Ga and then with a target constituted by metallic In within the chamber in a sputtering step. This sputtering step formed an Se-containing CuGa alloy layer (hereinafter referred to as “Cu—Ga—Se layer”) on the rear electrode, and an Se-containing In layer (hereinafter referred to as “In—Se layer”) on the CuGa alloy layer. This yielded a precursor layer constructed by the Cu—Ga—Se layer and the In—Se layer formed on the Cu—Ga—Se layer.

In the sputtering step, the Cu—Ga—Se layer had a thickness of 550 nm, while the In—Se layer had a thickness of 450 nm. The substrate temperature was 200° C., the flow ratio of H₂Se/Ar supplied into the chamber was 0.1, and the atmospheric pressure in the chamber was 1 Pa in the sputtering step.

In the heat treatment step subsequent to the sputtering step, the precursor layer was heated for 1 hr in an Ar atmosphere at 550° C., so as to form a p-type photo-absorbing layer (p-CIGS layer) having a composition expressed by CuIn_{0.7}Ga_{0.3}Se₂ with a thickness of 1 μm.

A CdS layer (n-type buffer layer) having a thickness of 50 nm was formed on the p-CIGS layer by chemical bath deposition. An i-ZnO layer (semi-insulating layer) having a thickness of 50 nm was formed on the CdS layer. A ZnO:Al layer (window layer) having a thickness of 1 μm was formed on the i-ZnO layer. A current collecting electrode (upper electrode), constituted by Al, having a thickness of 500 nm was formed on the ZnO:Al layer. The i-ZnO layer, ZnO:Al layer, and current collecting electrode were each formed by sputtering. The thin-film solar cell of Example 1 was thus obtained.

### Example 2

The thin-film solar cell of Example 2 was obtained by the same method as that of Example 1 except that a target constituted by In₂Se₃ was used in place of the target constituted by metallic In in the sputtering step, so as to form a precursor layer constructed by a Cu—Ga—Se layer and an In₂Se₃ layer formed thereon.

### Example 3

The thin-film solar cell of Example 3 was obtained by the same method as that of Example 2 except that the precursor layer was heated in the atmosphere while supplying thereto the H₂Se gas in addition to the Ar gas in the heat treatment step.

### Example 4

The thin-film solar cell of Example 4 was obtained by the same method as that of Example 1 except that Se vapor obtained by vaporizing solid Se was continuously supplied into the chamber instead of the H₂Se gas in the sputtering step.

### Example 5

The thin-film solar cell of Example 5 was obtained by the same method as that of Example 4 except that the precursor layer was heated in the atmosphere while supplying thereto Se vapor obtained by vaporizing solid Se in addition to the Ar gas in the heat treatment step.

### Comparative Example 1

In Comparative Example 1, only the Ar gas was continuously supplied into the atmosphere without the H₂Se gas in the sputtering step. Also, in Comparative Example 1, the precursor layer was heated in the atmosphere while supplying thereto the H₂Se gas in addition to the Ar gas in the heat treatment step. Except for these matters, the thin-film solar cell of Comparative Example 1 was obtained by the same method as that of Example 1.

### Comparative Example 2

In Comparative Example 2, only the Ar gas was continuously supplied into the atmosphere without the H₂Se gas in the sputtering step. Also, in Comparative Example 2, the precursor layer was heated in the atmosphere while supplying thereto the H₂Se gas in addition to the Ar gas in the heat treatment step. Except for these matters, the thin-film solar cell of Comparative Example 2 was obtained by the same method as that of Example 2.

Evaluation of Thin-Film Solar Cells

The carrier concentration, open-circuit voltage, short-circuit current, fill factor (F.F.), and conversion efficiency were determined in each of the solar cells of Examples 1 to 5 and Comparative Examples 1 and 2. Table 1 lists the results.

[Table 1]

TABLE 1

| | | | | | Open- | Short- | | |
|---|---|---|---|---|---|---|---|---|
| | | | Heat | | circuit | circuit | | Conversion |
| | Sputtering step | | treatment step | Carrier conc. | voltage | current | | efficiency |
| | Target | Atmosphere | Atmosphere | (cm⁻³) | (V) | (mA/cm²) | F.F. | (%) |
| Example 1 | CuGa | Ar | Ar | 4.50E+16 | 0.551 | 32.8 | 0.69 | 12.47 |
| | In | H₂Se | | | | | | |
| Example 2 | CuGa | Ar | Ar | 5.52E+16 | 0.586 | 33.0 | 0.70 | 13.54 |
| | In₂Se₃ | H₂Se | | | | | | |
| Example 3 | CuGa | Ar | H₂Se | 7.31E+16 | 0.601 | 33.2 | 0.71 | 14.17 |
| | In₂Se₃ | H₂Se | | | | | | |
| Example 4 | CuGa | Ar | Ar | 4.13E+16 | 0.560 | 31.9 | 0.68 | 12.15 |
| | In | Se (from solid) | | | | | | |
| Example 5 | CuGa | Ar | Se (from solid) | 6.93E+16 | 0.611 | 33.0 | 0.70 | 14.11 |
| | In | Se (from solid) | | | | | | |
| Comparative | CuGa | Ar | H₂Se | 1.20E+16 | 0.512 | 31.2 | 0.65 | 10.38 |
| Example 1 | In | | | | | | | |
| Comparative | CuGa | Ar | H₂Se | 2.21E+16 | 0.520 | 32.5 | 0.67 | 11.32 |
| Example 2 | In₂Se₃ | | | | | | | |

### REFERENCE SIGNS LIST

2 . . . solar cell; 4 . . . soda-lime glass sheet; 6 . . . rear electrode layer; 8 . . . p-type photo-absorbing layer (p-CIGS layer); 10 . . . n-type buffer layer (n-type semiconductor layer); 12 . . . semi-insulating layer; 14 . . . window layer (transparent conductive layer); 16 . . . upper electrode (lead electrode)

What is claimed is:

1. A method of manufacturing a solar cell, the method comprising:
a sputtering step of forming a layer containing Ib and IIIb group elements and Se on a substrate by sputtering with a target containing a Ib group element and a target containing a IIIb group element in an atmosphere containing Se; and
a heat treatment step of heating the layer.

2. A method of manufacturing a solar cell according to claim 1, wherein the sputtering step introduces H₂Se into the atmosphere.

3. A method of manufacturing a solar cell according to claim 1, wherein the sputtering step vaporizes solid Se and introduces thus vaporized Se into the atmosphere.

4. A method of manufacturing a solar cell according to claim 1, wherein the heat treatment step heats the layer in an atmosphere containing Se.

5. A method of manufacturing a solar cell according to claim 4, wherein the heat treatment step introduces H₂Se into the atmosphere.

6. A method of manufacturing a solar cell according to claim 4, wherein the heat treatment step vaporizes solid Se and introduces thus vaporized Se into the atmosphere.

7. A method of manufacturing a solar cell according to claim 1, wherein the Ib group element comprises Cu; and
wherein the IIIb group element comprises at least one of In and Ga.
